(19) United States
(12) Patent Application Publication
(10) Pub. No.: US 2013/0213466 A1
(43) Pub. Date: Aug. 22, 2013

(54) METHOD OF MANUFACTURING SOLAR CELL, AND SOLAR CELL

(71) Applicant: Tomohiro Soga, Kanagawa (JP)

(72) Inventor: Tomohiro Soga, Kanagawa (JP)

(73) Assignee: SUMITOMO HEAVY INDUSTRIES, LTD., Tokyo (JP)

(21) Appl. No.: 13/771,880

(22) Filed: Feb. 20, 2013

(30) Foreign Application Priority Data
Feb. 20, 2012 (JP) 2012-034286

(51) Int. Cl. H01L 31/18; H01L 31/0216; H01L 31/0236

(52) U.S. Cl. CPC H01L 31/18; H01L 31/0236; H01L 31/02168
USPC 136/256; 438/72

(57) ABSTRACT

A method of manufacturing a solar cell includes forming an emitter layer on a light-receiving surface side of a substrate for a solar cell, forming an antireflection film, patterned so as to expose a part of the light-receiving surface of the substrate, on the substrate, forming a contact region by implanting an impurity to the exposed part by using the antireflection film as a mask, and forming a light-receiving surface electrode on the contact region.

### BACKGROUND OF THE INVENTION

1. Field of the Invention

The present invention relates to a method of manufacturing a solar cell, and a solar cell.

2. Description of the Related Art

In a solar cell, electron-hole pairs are generated when a semiconductor material such as silicon absorbs light. In an electric field such as in a p-n junction formed within the cell, the electron-hole pairs are extracted as an electric current to an external circuit by electrons moving to the n-layer side and holes moving to the p-layer side. In the formation of a p-n junction and a contact layer, processing of locally varying the concentration and the type of impurity is required.

Furthermore, in order to increase light to be captured inside the solar cell as much as possible, an antireflection film is formed on a light-receiving surface side of a silicon substrate. Therefore, conduction between a part of an emitter layer of the silicon substrate and a light-receiving surface electrode needs to be made across the antireflection film.

For example, there has been known a method of manufacturing a solar cell in which an antireflection film is printed with a silver paste in a predetermined pattern and is burned at a high temperature. By doing so, a part of silver paste ingredients is caused to infiltrate the antireflection film, and conduction is achieved with an emitter layer having a high impurity concentration.

### SUMMARY OF THE INVENTION

A method of manufacturing a solar cell according to an aspect of the present invention includes: forming an emitter layer on a light-receiving surface side of a substrate for a solar cell; forming an antireflection film, patterned so as to expose a part of the light-receiving surface of the substrate, on the substrate; forming a contact region by implanting an impurity to the exposed part by using the antireflection film as a mask; and forming a light-receiving surface electrode on the contact region.

Another aspect of the present invention is also a method of manufacturing a solar cell. This method includes: forming an emitter layer on a light-receiving surface side of a substrate for a solar cell; forming a contact region, having a higher impurity concentration than other regions, in a predetermined region of the emitter layer; forming an antireflection film, patterned so as to expose the contact region, on the substrate; and forming a light-receiving surface electrode on the contact region.

Still another aspect of the present invention is also a method of manufacturing a solar cell. This method includes: forming an antireflection film, patterned so as to expose a part of a light-receiving surface of a substrate for a solar cell, on the substrate; and forming a light-receiving surface electrode on the exposed part of the substrate.

Still another aspect of the present invention is a solar cell. This solar cell includes: a semiconductor substrate on which an emitter layer is formed, an antireflection film which covers the emitter layer and is patterned so as to form a penetrated portion; and a light-receiving surface electrode provided in the penetrated portion formed in the antireflection film.

### BRIEF DESCRIPTION OF THE DRAWINGS

FIG. 1 is a flowchart of a method of manufacturing a solar cell according to a first embodiment;

FIGS. 2A to 2E are schematic sectional views of a semiconductor substrate in each step of the method of manufacturing a solar cell according to the first embodiment;

FIGS. 3A to 3D are schematic sectional views of a semiconductor substrate in each step of the method of manufacturing a solar cell according to the first embodiment;

FIG. 4 is a flowchart of a method of manufacturing a solar cell according to a second embodiment;

FIGS. 5A to 5D are schematic sectional views of a semiconductor substrate in each step of the method of manufacturing a solar cell according to the second embodiment; and

FIGS. 6A to 6C are schematic sectional views of a semiconductor substrate in each step of the method of manufacturing a solar cell according to the second embodiment.

### DETAILED DESCRIPTION OF THE INVENTION

The invention will now be described by reference to the preferred embodiments. This does not intend to limit the scope of the present invention, but to exemplify the invention.

In the above-described method of manufacturing, it is necessary to cause the silver paste appropriately infiltrate the emitter layer having a high impurity concentration through an antireflection film. Therefore, in the cases where an appropriate electrode paste is not selected or where a burning condition is not accurate, conversion efficiency may be lowered due to increased contact resistance, or an electrode may be infiltrated too deep and therefore a problem of passing through may occur in the p-n junction layer.

One of exemplary objects according to an aspect of the present invention is to provide a technology for realizing highly reliable low-resistance conduction between an electrode and a substrate of a solar cell.

Hereinafter, embodiments for carrying out the present invention are described in details. Note that configurations described herein are only exemplification and not intended to limit the scope of the present invention in any way. In a description of the figures, similar reference numerals are used for identical constituent elements in order to avoid any duplicated description when appropriate. Furthermore, in the sectional views provided to explain a method of manufacturing, the thickness and the size of a semiconductor substrate and other layers are provided for an exemplary purpose only, and do not necessarily represent the actual size or ratio.

### FIRST EMBODIMENT

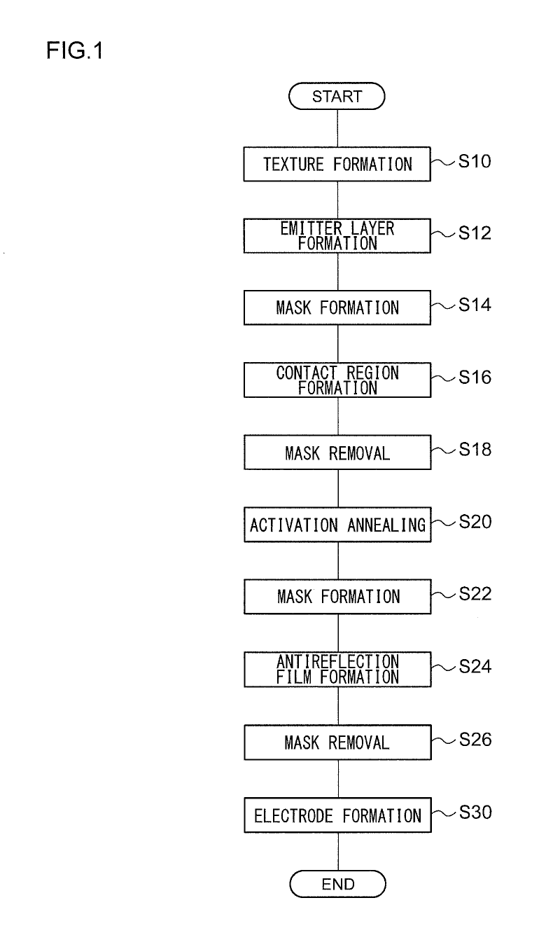

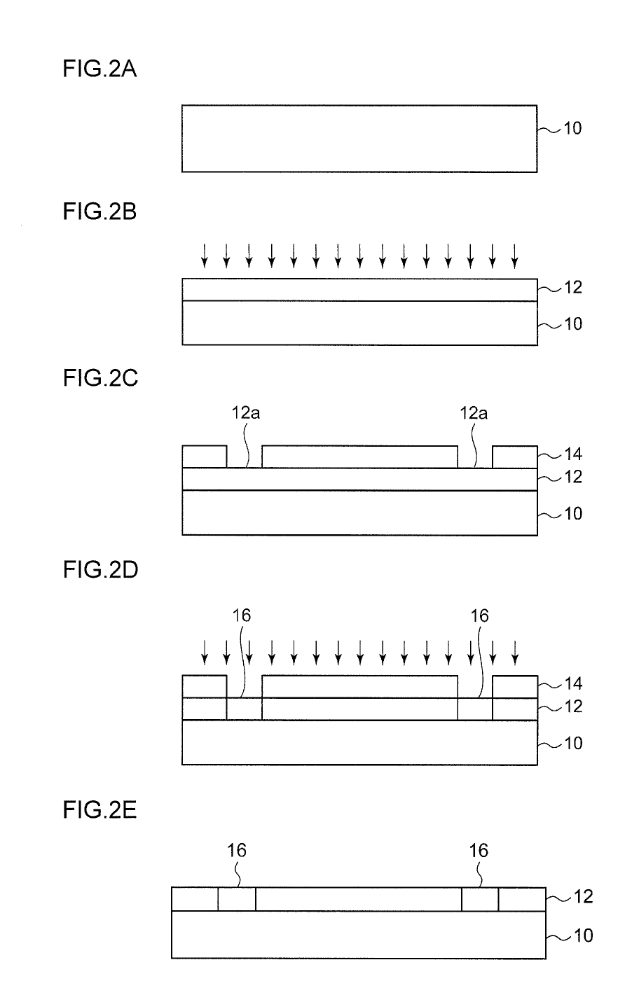

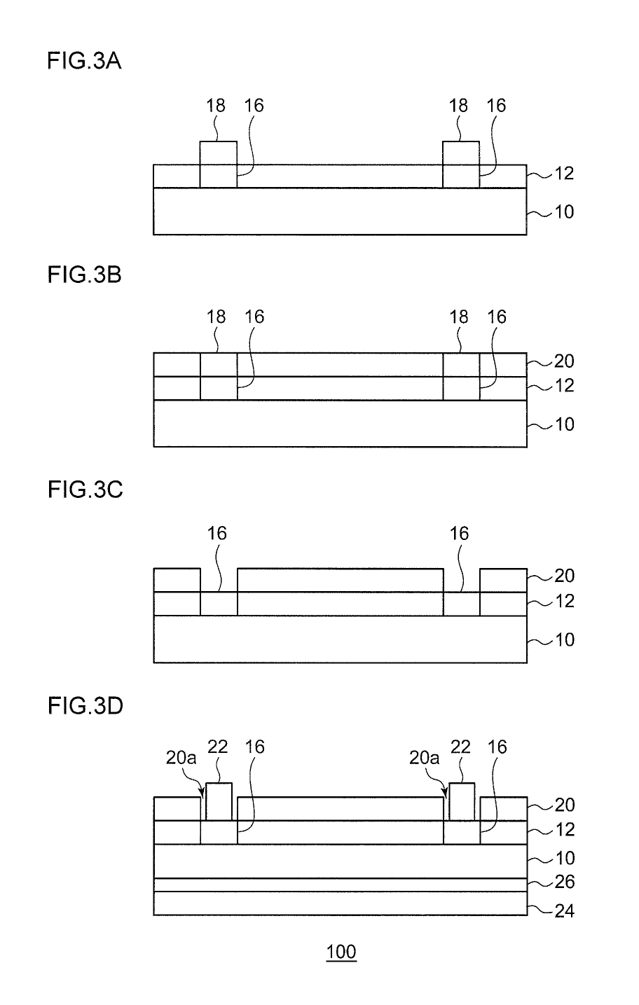

FIG. 1 is a flowchart of a method of manufacturing a solar cell according to a first embodiment. FIGS. 2A to 2E are schematic sectional views of a semiconductor substrate in each step of the method of manufacturing a solar cell according to the first embodiment. FIGS. 3A to 3D are schematic sectional views of a semiconductor substrate in each step of the method of manufacturing a solar cell according to the first embodiment.

In this embodiment, a case of using a p-type monocrystalline silicon substrate as a semiconductor substrate is described, but the present invention is also applicable to the cases where an n-type silicon substrate, a polycrystalline substrate, or a p-type/n-type compound semiconductor substrate is used. A method of manufacturing a solar cell according to this embodiment is described below with reference to FIGS. 1 to 3D.

First, as shown in FIG. 2A, a p-type silicon substrate 10 is prepared by slicing a monocrystalline silicon ingot with a multi-wire method. Next, any damage on the substrate surface caused by slicing is removed with an alkaline solution, and microasperity (or a texture, not shown in FIG. 2A) with a maximum height of about 10μm is formed on the light-receiving surface (S10 in FIG. 1). Due to scattering caused by such a microasperity, a light trapping effect is obtained, which contributes to improving conversion efficiency.

Then, as shown in FIG. 2B, an n-type emitter layer 12 is formed by implanting an n-type dopant, having an opposite conductivity type to the substrate, to all areas of the light-receiving surface of the substrate by ion implantation (S12 in FIG. 1).

Then, as shown in FIG. 2C, a mask patterned so as to expose a predetermined region of the emitter layer 12 is formed (S14 in FIG. 1). A mask that is formed with a photolithographic or printing method as well as a hard mask can be used.

Then, as shown in FIG. 2D, an n-type dopant, having an opposite conductivity type to the substrate, is implanted again to all areas of the light-receiving surface of the substrate by ion implantation. At this time, an ion is implanted selectively to a predetermined exposed region 12a (see FIG. 2C) of the emitter layer 12 that is not coated with a mask. Accordingly, a contact region 16 having a higher impurity concentration than other regions is formed (S16 in FIG. 1) in a predetermined region of the emitter layer 12. A method of forming a contact region having a high impurity concentration by selectively implanting an ion to a part of a substrate in this manner is called the selective emitter. By performing ion implantation after masking a region not requiring the ion implantation by using such a method, a selective ion implantation pattern corresponding to an unmasked region is formed in a predetermined region of the substrate.

Then, as shown in FIG. 2E, a mask 14 is removed from the silicon substrate 10 (S18 in FIG. 1), and an activation annealing treatment is performed to the entire substrate (S20 in FIG. 1).

Then, as shown in FIG. 3A, a mask 18 is formed so as to mask the contact region 16 (S22 in FIG. 1). Then, as shown in FIG. 3B, an antireflection film 20 including SiN, TiO₂ or the like, is formed with a method such as the chemical vapor deposition (CVD) on a region not masked by the mask 18 on the surface of the emitter layer 12 (S24 in FIG. 1). The thickness of the antireflection film 20 is, for example, about 10 to 100 nm. Subsequently, as shown in FIG. 3C, the mask 18 is removed from the silicon substrate 10 (S26 in FIG. 1). By these steps, the antireflection film 20 patterned so as to expose the contact region 16 can be formed on the substrate.

Then, as shown in FIG. 3D, a light-receiving surface electrode 22 is formed directly on the contact region 16 along the pattern of the antireflection film 20 (S30 in FIG. 1). The light-receiving surface electrode 22 is formed by printing with a light-receiving surface electrode paste including silver (Ag) as a main ingredient in a comb shape having a width of about 50 to 100 μm, for example, and then by burning the paste. The height of the light-receiving surface electrode 22 is about 10 to 50μm.

Furthermore, an underside surface electrode 24 is also formed at this stage by printing with an underside surface electrode paste including aluminum (Al) as a main ingredient, and then by burning the paste. At this time, the Al included in the paste is diffused into the silicon substrate 10, and a p+ layer 26 is formed near the underside surface electrode 24. Accordingly, a back surface field (BSF) effect can be obtained.

Note that the activation annealing treatment can also be performed after the ion implantation and between S18 and S30 in FIG. 1, when appropriate. Furthermore, in the case where a method other than the ion implantation, such as the thermal diffusion method, is used for forming the emitter layer in S12 and the contact region in S16, the activation annealing treatment may be skipped.

By the above steps, a solar cell 100 is manufactured. The solar cell 100 includes the silicon substrate 10 on which the emitter layer 12 is formed, the antireflection film 20 which covers the emitter layer 12 and is patterned so as to form a penetrated portion 20a, and the light-receiving surface electrode 22 provided in the penetrated portion 20a, which is formed in the antireflection film 20 so as to penetrate to the emitter layer 12 of the silicon substrate 10. The penetrated portion 20a is formed above the contact region 16 where the impurity concentration is higher than other regions of the emitter layer 12.

Since the light-receiving surface electrode 22 is formed directly on the contact region 16 and not via the antireflection film 20, it is easier to select a paste material for forming the light-receiving surface electrode 22 as well as select and manage a burning condition of the paste material. As a result, low-resistance conduction is realized between the silicon substrate 10 and the light-receiving surface electrode 22.

A method of manufacturing the solar cell 100 according to this embodiment, in other words, includes forming the antireflection film 20, patterned so as to expose a part of the light-receiving surface of the silicon substrate 10 for the solar cell, on the silicon substrate 10, and forming the light-receiving surface electrode 22 on the exposed part of the silicon substrate 10 by using the antireflection film 20 as a mask.

### SECOND EMBODIMENT

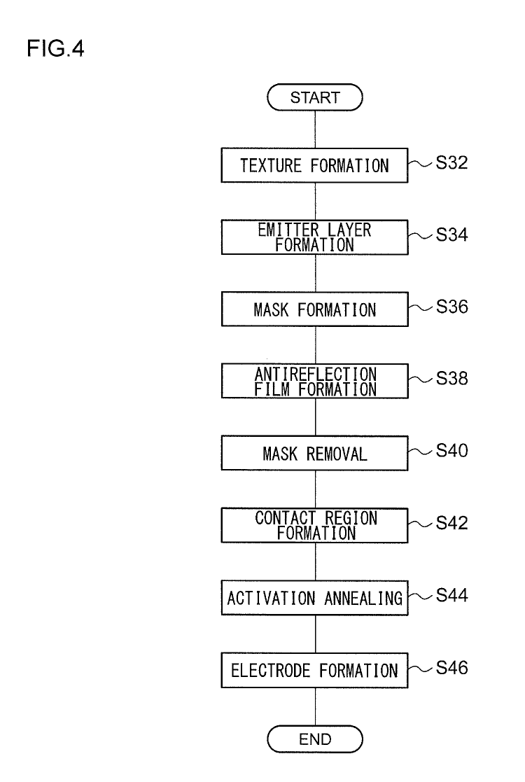

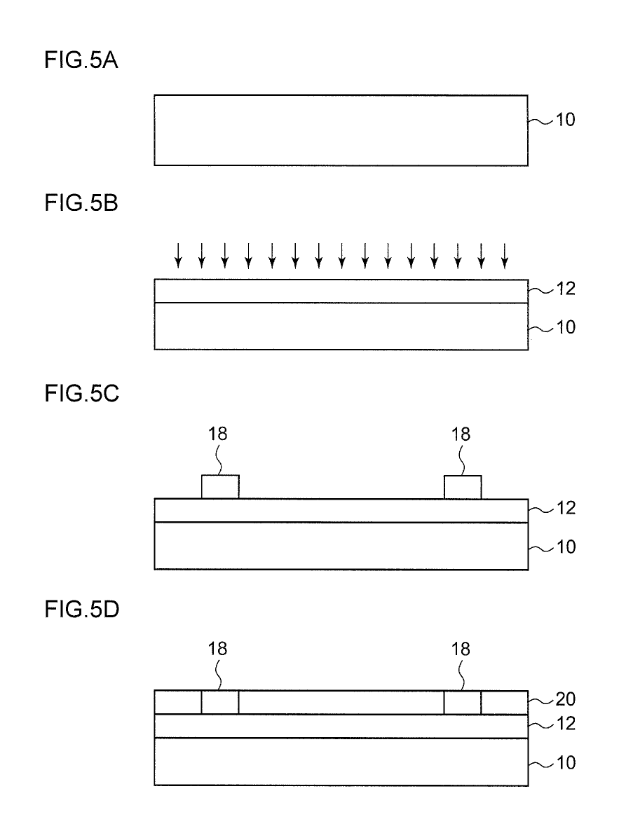

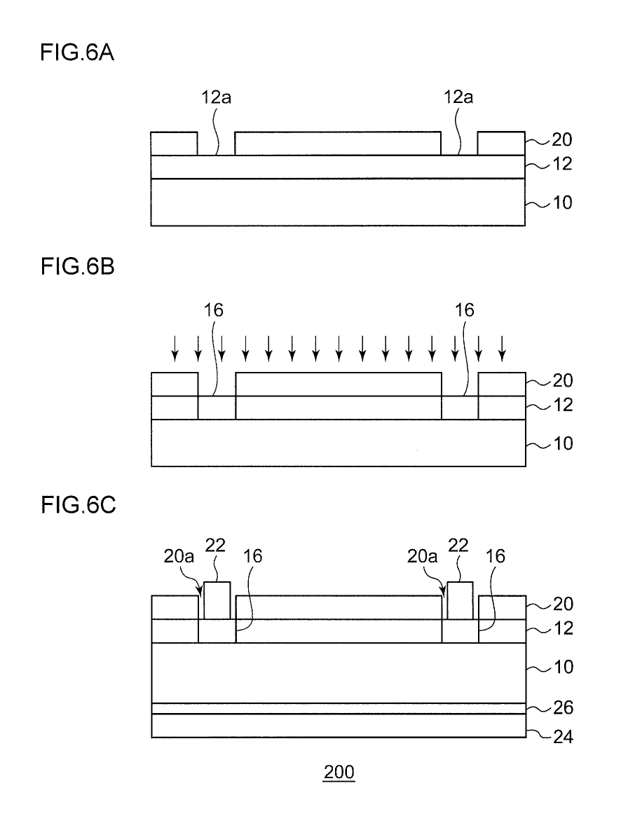

FIG. 4 is a flowchart of a method of manufacturing a solar cell according to a second embodiment. FIGS. 5A to 5D are schematic sectional views of a semiconductor substrate in each step of the method of manufacturing a solar cell according to the second embodiment. FIGS. 6A to 6C are schematic sectional views of a semiconductor substrate in each step of the method of manufacturing a solar cell according to the second embodiment.

Hereinafter, a method of manufacturing a solar cell according to this embodiment is described with reference to FIGS. 4 to 6. Note that descriptions are omitted when appropriate for configurations and steps identical to those in the first embodiment.

First, as shown in FIG. 5A, a p-type silicon substrate 10 is prepared by slicing a monocrystalline silicon ingot with a multi-wire method. Next, any damage on the substrate surface caused by slicing is removed with an alkaline solution, and microasperity (or a texture, not shown in FIG. 5A) with a maximum height of about 10 μm is formed on the light-receiving surface (S32 in FIG. 4).

Then, as shown in FIG. 5B, an n-type emitter layer 12 is formed by implanting an n-type dopant, having an opposite conductivity type to the substrate, to all areas of the light-receiving surface of the substrate by ion implantation (S34 in FIG. 4).

Then, as shown in FIG. 5C, a mask 18 is formed so as to mask a predetermined region corresponding to a contact region formed by selective emitter, which is described later (S36 in FIG. 4). Then, as shown in FIG. 5D, an antireflection film 20 including SiN, TiO₂ or the like, is formed with a method such as the CVD on a region not masked by the mask 18 on the surface of the emitter layer 12 (S38 in FIG. 4). Then, as shown in FIG. 6A, the mask 18 is removed from the silicon substrate 10 (S40 in FIG. 1). By these steps, the antireflection film 20 patterned so as to expose a part of the light-receiving surface of the silicon substrate 10 can be formed on the silicon substrate 10.

Then, as shown in FIG. 6B, an n-type dopant, having an opposite conductivity type to the silicon substrate 10, is implanted again to all areas of the light-receiving surface of the silicon substrate 10 by ion implantation. At this time, a contact region 16 is formed by implanting an impurity to the exposed region by using the antireflection film 20 as a mask. In other words, an ion is implanted selectively to a predetermined exposed region 12a (see FIG. 6A) of the emitter layer 12 that is not coated with the antireflection film 20. Accordingly, the contact region 16 having a higher impurity concentration than other regions is formed in a predetermined region of the emitter layer 12 (S42 in FIG. 4). Subsequently, an activation annealing treatment is performed to the entire substrate (S44 in FIG. 4).

Here, depending on energy of the n-type dopant in the ion implantation, the n-type dopant may penetrate through the antireflection film 20 and reach the emitter layer, which may lower the performance of the emitter layer. Therefore, in order to prevent most of the n-type dopants, which have been implanted to the antireflection film 20, from reaching the emitter layer, the film thickness of the antireflection film 20 and the energy of the ion implantation should be selected appropriately.

Then, as shown in FIG. 6C, a light-receiving surface electrode 22 is formed directly on the contact region 16 along the pattern of the antireflection film 20 (S46 in FIG. 4). A method of forming the light-receiving surface electrode 22 is the same as in the first embodiment. Furthermore, an underside surface electrode 24 is also formed at this stage. A method of forming the underside surface electrode 24 is the same as in the first embodiment. At this time, the Al included in the underside surface electrode paste is diffused into the silicon substrate 10, and a p+ layer 26 is formed near the underside surface electrode 24. Accordingly, a back surface field (BSF) effect can be obtained.

By the above steps, a solar cell 200 having the same configuration as the solar cell 100 in the first embodiment is manufactured. Since the light-receiving surface electrode 22 is formed directly on the contact region 16 and not via the antireflection film 20, it is easier to select a paste material for forming the light-receiving surface electrode 22 as well as select and manage a burning condition of the paste material. Furthermore, compared to a method of manufacturing according to the first embodiment, a method of manufacturing according to the second embodiment does not use two different masks but uses the antireflection film 20 as one of the masks, and therefore the number of dedicated masks can be reduced. Then, by self-alignment using a pattern of the antireflection film 20, the contact region 16 is formed along the exposed region of the emitter layer 12. As a result, alignment accuracy is improved, and low-resistance conduction is realized between the silicon substrate 10 and the light-receiving surface electrode 22.

A method of manufacturing the solar cell 200 according to this embodiment, in other words, also includes forming the antireflection film 20, patterned so as to expose a part of the light-receiving surface of the silicon substrate 10 for the solar cell, on the silicon substrate 10, and forming the light-receiving surface electrode 22 on the exposed contact region 16 of the silicon substrate 10 by using the antireflection film 20 as a mask.

In this method, since the contact region 16 is formed along the exposed region of the emitter layer 12 by using the antireflection film 20 as a mask, an alignment between the light-receiving surface electrode 22 and the contact region 16 of the substrate can be achieved easily and accurately. Furthermore, since the light-receiving surface electrode 22 is formed directly on the contact region 16 and not via the antireflection film 20, selection of a paste material for forming the light-receiving surface electrode 22 as well as selection and management of a burning condition of the paste material become easier. As a result, alignment accuracy is improved, and low-resistance conduction is realized between the silicon substrate 10 and the light-receiving surface electrode 22.

Furthermore, the range of implantation of doping ion when forming the contact region 16 in the emitter layer 12 by ion implantation is selected not to exceed the film thickness of the antireflection film 20. Therefore, an ion implanted to the antireflection film 20 does not reach the emitter layer 12 by permeating through the antireflection film 20, and most of the ions remain in the antireflection film 20. As a result, the amount of dose to the emitter layer 12 is not affected significantly.

Furthermore, as a mask in Step S36 in FIG. 4 (corresponding to FIG. 5C), a hard mask, a stencil mask, or the like that can come into and out of contact with the substrate surface in a vacuum apparatus may be used. Accordingly, processing from Steps S34 to S42 in FIG. 4 can be performed in a series of vacuum environments without returning to an atmospheric environment once, and therefore an in-line apparatus is realized easily. Note that as a mask, a wire or the like may be used depending on the shape and the size of the region to be masked. Furthermore, in Step S44 of FIG. 4, by using an annealing method capable of treatment within a vacuum apparatus, such as a flash lamp, processing from Steps S34 to S44 in FIG. 4 can be performed in a series of vacuum environments without returning to an atmospheric environment once.

As described above, according to the embodiments of a method of manufacturing a solar cell, it is not necessary to infiltrate inside the antireflection film 20 to have conduction with the silicon substrate 10 when burning the light-receiving surface electrode 22, and therefore the burning conditions can be widened, realizing easier control and quality stabilization of the solar cell.

As above, the present invention has been described by referring to the above-described embodiments, but the present invention is not intended to be limited to the above-described embodiments, and any embodiment that appropriately combines or alters configurations in the above-described embodiments is also included in the present invention. Furthermore, based on the knowledge of those skilled in the art, modifications such as various types of design changes may be added to an ion implantation apparatus and/or a carrier according to the above-described embodiments, and any embodiment with such modifications may also be included in the scope of the present invention.

It should be understood that the invention is not limited to the above-described embodiment, but may be modified into various forms on the basis of the spirit of the invention. Additionally, the modifications are included in the scope of the invention.

Priority is claimed to Japanese Patent Application No. 2012-034286, filed Feb. 20, 2012, the entire content of which is incorporated herein by reference.

What is claimed is:

1. A method of manufacturing a solar cell, comprising:
forming an emitter layer on a light-receiving surface side of a substrate for a solar cell;
forming an antireflection film, patterned so as to expose a part of the light-receiving surface of the substrate, on the substrate;
forming a contact region by implanting an impurity to the exposed part by using the antireflection film as a mask; and
forming a light-receiving surface electrode on the contact region.

2. A method of manufacturing a solar cell, comprising:
forming an emitter layer on a light-receiving surface side of a substrate for a solar cell;
forming a contact region, having a higher impurity concentration than other regions, in a predetermined region of the emitter layer;
forming an antireflection film, patterned so as to expose the contact region, on the substrate; and
forming a light-receiving surface electrode on the contact region.

3. A method of manufacturing a solar cell, comprising:
forming an antireflection film, patterned so as to expose a part of a light-receiving surface of a substrate for a solar cell, on the substrate; and
forming a light-receiving surface electrode on the exposed part of the substrate.

4. A solar cell comprising:
a semiconductor substrate on which an emitter layer is formed;
an antireflection film which covers the emitter layer and is patterned so as to form a penetrated portion; and
a light-receiving surface electrode provided in the penetrated portion formed in the antireflection film.
